(19) United States
(12) Patent Application Publication
(10) Pub. No.: US 2026/0079411 A1
(43) Pub. Date: Mar. 19, 2026

(54) OPTICAL ELEMENT FOR THE ULTRAVIOLET WAVELENGTH RANGE

(71) Applicant: CARL ZEISS SMT GMBH, Oberkochen (DE)

(72) Inventor: Alexandra PAZIDIS, Oberkochen (DE)

(21) Appl. No.: 19/396,805

(22) Filed: Nov. 21, 2025

Related U.S. Application Data
(63) Continuation of application No. PCT/EP2024/063558, filed on May 16, 2024.

(30) Foreign Application Priority Data
May 22, 2023 (DE) 10 2023 204 746.2

(51) Int. Cl. G03F 7/00

(52) U.S. Cl. CPC G03F 7/70958; G03F 7/7015; G03F 7/70316

(57) ABSTRACT

In order to increase transmission or reflection, an optical element for the ultraviolet (UV) wavelength range is proposed, comprising a substrate and an optical coating configured as a dielectric layer system, the dielectric layer system comprising layers of at least two different base materials with different refractive indices at a wavelength in the UV wavelength range, which are arranged alternately, wherein the optical element comprises a nanolayer system at the position of at least one layer of the base material with the higher refractive index.

### CROSS REFERENCE TO RELATED APPLICATIONS

This is a Continuation of International Application PCT/EP2024/063558, which has an international filing date of May 16, 2024, and which claims the priority of German Patent Application 10 2023 204 746.2, filed May 22, 2023. The disclosures of both applications are incorporated in their respective entireties into the present Continuation by reference.

### FIELD

The techniques of the present disclosure relate to an optical element for the ultraviolet (UV) wavelength range, including the vacuum ultraviolet range (VUV) comprising a substrate and an optical coating configured as a dielectric layer system, the dielectric layer system comprising layers of at least two different base materials with different refractive indices at a wavelength in the UV wavelength range, which are arranged alternately. The techniques disclosed herein further relate to an optical system having such an optical element.

### BACKGROUND

Optical elements for the UV wavelength range must satisfy high requirements, especially for applications in the shorter-wave UV wavelength range, for example approximately 100 nm to 300 nm. In this regard, depending on whether they are reflective or transmissive optical elements, it may be beneficial that the reflection or the transmission be as high as possible. Moreover, the lifetime should also be, as far as possible, in the range of several years. Optical elements for the UV wavelength range usually comprise a substrate and an optical coating configured as a dielectric layer system, the dielectric layer system comprising layers of at least two different base materials with different refractive indices at a wavelength in the UV wavelength range, in order to improve the transmission or reflection of the optical element. Said optical coating may also contribute to increasing the lifetime, to a certain extent. Especially for use in reflection, the optical coating may additionally comprise a metal layer on the substrate side.

### SUMMARY

It is an object of the techniques disclosed herein to propose optical elements for, in particular, the shorter-wave UV wavelength range.

This object may be achieved by an optical element for the UV wavelength range, comprising a substrate and an optical coating configured as a dielectric layer system, the dielectric layer system comprising layers of at least two different base materials with different refractive indices at a wavelength in the UV wavelength range, which are arranged alternately, wherein the optical element comprises a nanolayer system at the position of at least one layer of the base material with the higher refractive index.

It has been found that both the reflection or transmission and the lifetime can be improved by providing at least one nanolayer system, specifically at the position of a layer of higher refractive index base material. In contrast to the known dielectric layer systems in which the transmission or reflection is increased by means of interference for optical layer thicknesses of substantially the quarter of the incident wavelength, nanolayer systems are structures which are constructed from a plurality of layers having thicknesses in the nanometer range and with the aid of which the refractive index and the absorption of the respective nanolayer system can be directly influenced. In order to improve the optical properties of the at least partly replaced layer, it is advantageous if at least some of the nanolayers are likewise produced from one or more materials having a refractive index comparable to or higher than that of the replaced material. A lower absorption increases the transmission or the reflection of an optical element having a dielectric layer system modified by nanolayer systems. By virtue of less radiation being absorbed in the respective dielectric layer system, less energy is deposited in the optical system, energy which might otherwise result in degradation of the dielectric system. For example, this energy may cause expansion of individual layers with a corresponding change in optical parameters and occurrence of stresses, which may result in bursting apart of individual layers.

Advantageously, the at least one layer of the base material with the higher refractive index is at least partly replaced by the nanolayer system. In particular embodiments, one or more layers of the higher refractive index base material can even be completely replaced by a nanolayer system in order to improve transmission or reflection of the optical element as well as the lifetime thereof.

In particular embodiments, the optical element is designed for a wavelength of between 190 nm and 300 nm, preferably between 190 nm and 200 nm. In this UV wavelength range, providing a nanolayer system at the position of at least one layer of higher refractive index base material has a particularly positive effect on, firstly, the transmission or reflection of the optical element and, secondly, the lifetime thereof.

Preferably, the at least one nanolayer system is constructed from at least two different nanolayer materials with different refractive indices at a wavelength in the UV wavelength range, which are arranged alternately, in order that the refractive index and absorption of the resulting nanolayer system, and thus of the dielectric layer system of the optical element, can be influenced in as targeted a manner as possible and without too much outlay/complexity.

It has been found to be particularly advantageous if the higher and/or lower refractive index nanolayer material is the same as the respective higher and/or lower refractive index base material. The layers of the dielectric layer system and also the layers of the nanolayer system(s) can thus be applied to the respective optical element in a continuous process without modification or transfer into a different coating chamber.

Preferably, in particular for the use of the optical element in conjunction with shorter-wave UV radiation, the base material with the higher refractive index is an oxide, in particular one or more of the materials of the group consisting of Al₂O₃, MgAl₂O₄, Lu₃Al₅O₁₂, GeO₂, CaO, MgO, HfO₂, Si₃N₄, Y2O₃ and La₂O₃. These materials are suitable for wavelengths of the incident radiation in the range of 100 nm to 300 nm, preferably in the range of 190 nm to 300 nm, and particularly preferably in the range of 190 nm to 200 nm.

It is likewise preferred, in particular for the use of the optical element in conjunction with shorter-wave UV radiation, for the base material with the lower refractive index to be silicon dioxide and/or an amorphous fluoropolymer. These materials are suitable for wavelengths of the incident radiation in the range of 100 nm to 300 nm, preferably in the range of 190 nm to 300 nm, and particularly preferably in the range of 190 nm to 200 nm.

It is particularly advantageous if the layers of the nanolayer system(s) also each comprise one or more of these materials, in particular if the at least one nanolayer system is constructed from at least two different nanolayer materials with different refractive indices at a wavelength in the UV wavelength range, which are arranged alternately, and the higher and/or lower refractive index nanolayer material is the same as the respective higher and/or lower refractive index base material of the dielectric layer system of the optical element.

In particularly preferred embodiments, the optical coating is designed as a reflection coating, wherein the reflection coating can be embodied as purely dielectric coating or can additionally comprise a metal layer as reflective coating. Advantageously, in particular in the former case, the at least one layer comprising a nanolayer system is arranged in the third of the optical coating that faces away from the substrate. Preferably, in this case, the optical element comprises a nanolayer system at the position of at least one of the seven layers with the higher refractive index that are arranged the furthest facing away from the substrate. Advantageously, in this case, the optical element comprises a nanolayer system at all positions of the respective three, four, five, six or seven layers with the higher refractive index that are arranged the furthest facing away from the substrate. It has been found that in the region of the dielectric layer system that faces away from the substrate, i.e., in the region situated closer or adjacent to the outer surroundings of the optical element, providing nanolayer systems can have a particularly large influence on the increase in the reflection of the optical element.

Advantageously, in the case of reflection coatings with or without metal reflective coating, on at least one layer with the higher refractive index, the latter is replaced by the nanolayer system at the side facing the substrate. In many cases where there is no desire for the entire layer to be replaced by a nanolayer system, a significant effect of the nanolayer system on transmission or reflection and also on the lifetime of the optical element can be achieved if said nanolayer system is arranged at the substrate-facing side of the relevant layer of higher refractive index material. This effect is particularly pronounced if, in the case of at least one of the three layers with the higher refractive index that are the furthest away from the substrate, this is replaced by a nanolayer system at the side facing the substrate.

In a further preferred embodiment, the optical coating is designed as an antireflection coating, wherein the optical element comprises no nanolayer system at the position of the layer arranged the furthest facing away from the substrate. It has been found that providing at least one nanolayer system in the optical coating is advantageous in the case of the embodiment as a transmissive optical element, the transmission can be particularly increased if no nanolayer system is arranged at the position of the layer arranged the furthest facing away from the substrate.

It has likewise proved to be advantageous, with regard to transmission or reflection and with regard to the lifetime of the optical element, if, at the at least one layer with the higher refractive index, the latter is replaced by a nanolayer system both at the side facing the substrate and at the side facing away from the substrate. In this case, preferably, both nanolayer systems are constructed from the same materials.

Overall it has proved to be advantageous if, at the at least one layer with the higher refractive index, at least half of the latter is replaced by a nanolayer system. In particular, if the relevant at least one layer is arranged in the third facing away from the substrate, the nanolayer system may have a particularly great influence on the transmission or reflection and also the lifetime of the optical element.

Upon reflection of a wavelength in the UV wavelength range, a standing wave of an electric field forms in the optical element, specifically in the dielectric layer system. In particularly preferred embodiments, the optical element, at the at least one layer with the higher refractive index, comprises a nanolayer system at a point of extremal field intensity of the standing wave. This makes it possible to particularly effectively influence the absorption of the dielectric layer system, and thus both transmission or reflection and the lifetime of the optical element.

Furthermore, the object of this disclosure may be achieved by an optical system comprising an optical element as described. Such optical systems are well suited inter alia as parts of lithography apparatuses and of wafer and/or mask inspection systems, but also of optical systems for the use of lasers, in particular for use in the UV wavelength range.

### BRIEF DESCRIPTION OF THE DRAWINGS

The techniques of the present disclosure will be explained in greater detail with reference to preferred exemplary embodiments. In this respect:

FIG. 1 shows a basic schematic diagram of a UV lithography apparatus;

FIG. 2 shows a basic schematic diagram of an inspection system;

FIG. 3 schematically shows an optical element having a dielectric layer system;

FIG. 4 schematically shows a layer pair having a nanolayer system;

FIG. 5 schematically shows a layer pair having two nanolayer systems;

FIG. 6 shows the reflection at a first optical element at 193 nm as a function of the angle of incidence;

FIG. 7 shows the construction of the dielectric layer system of the first optical element;

FIG. 8 shows the standing wave that forms upon reflection at the first optical element;

FIG. 9 shows the reflection at a second optical element at 193 nm as a function of the angle of incidence;

FIG. 10 shows the construction of the dielectric layer system of the second optical element;

FIG. 11 shows the construction of the dielectric layer system of a third optical element; and

FIG. 12 shows the reflection at the third optical element at 193 nm as a function of the angle of incidence.

### DETAILED DESCRIPTION

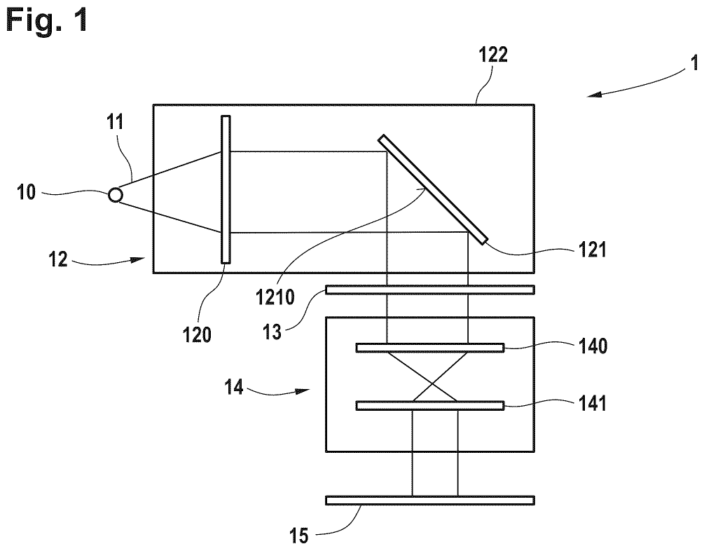

FIG. 1 shows a basic schematic diagram of an apparatus 1 for UV lithography, in particular for wavelengths in the range of 190 nm to 300 nm. The UV lithography apparatus 1 comprises, as essential components, in particular two optical systems 12, 14, an illumination system 12 and a projection system 14. Carrying out the lithography necessitates a radiation source 10, such as an excimer laser, which emits radiation at, for example, 193 nm or 248 nm and which can be an integral part of the UV lithography apparatus. The radiation 11 emitted by the radiation source 10 is conditioned with the aid of the illumination system 12 such that a mask 13, also called a reticle, can be illuminated thereby. In the example illustrated here, the illumination system 12 comprises transmissive and reflective optical elements. The transmissive optical element 120, which focuses the radiation 11, for example, and the reflective optical element 121, which deflects the radiation, for example, are illustrated here in representative fashion. In a known manner, in the illumination system 12, a wide variety of transmissive, reflective and other optical elements can be combined with one another in a more complex, manner. It should be pointed out that the mask 13 can also be embodied as a reflective or transmissive optical element as proposed here.

The mask 13 has a structure on its surface, said structure being transferred to an element 15 to be exposed, for example a wafer in the context of the production of semiconductor components, with the aid of the projection system 14. In the present example, the mask 13 is embodied as a transmissive optical element. In further embodiments, it can also be configured as a reflective optical element. The projection system 14 comprises at least one transmissive optical element in the example illustrated here. In the example illustrated here, two transmissive optical elements 140, 141 are illustrated in representative fashion, which serve, for example, to reduce the structures on the mask 13 to the size desired for the exposure of the wafer 15. In the projection system 14, too, inter alia reflective optical elements can be provided and a wide variety of optical elements can be combined with one another in a known manner. It should be pointed out that optical systems without transmissive optical elements can also be provided, in particular in the case of optical systems which are optimized for wavelengths of less than 200 nm.

The reflective optical element 121 is a mirror having a reflective surface 1210 comprising an optical coating in the form of a dielectric layer system having at least one nanolayer system. In the present example, the reflective optical element 121 comprises a metal reflective coating below the dielectric layer system. The dielectric layer system not only improves the reflection, especially in the range of a specific wavelength, for example at the emission wavelength of an excimer laser if the latter is used as a radiation source, but can also protect the metal reflective coating from oxidation and other impairments. In order to be able to be used with good reflectivity, in particular over a wide wavelength range, for example 190 nm to 300 nm, a metal layer composed of aluminum has proved worthwhile as a metal reflective coating. Further suitable metals are noble metals and platinum metals, in particular for use with grazing incidence. It should be pointed out that in connection with the example illustrated in FIG. 1, although only one reflective optical element 121 for the UV wavelength range is discussed, it goes without saying that two, three, four, five or more reflective optical elements of this type can be provided in an optical system for UV lithography, for instance.

The UV lithography apparatus illustrated in FIG. 1 also comprises transmissive optical elements, configured as lenses 120, 140, 141 in the present example. The latter, at least on their front side in the beam path, likewise comprise an optical coating in the form of a dielectric layer system having at least one nanolayer system. The dielectric layer system acts as an antireflection coating and can thus increase the transmission of the respective lens. Especially in optical systems for UV lithography, more than one or two, namely three, four, five, six, seven or more transmissive optical elements can also be provided.

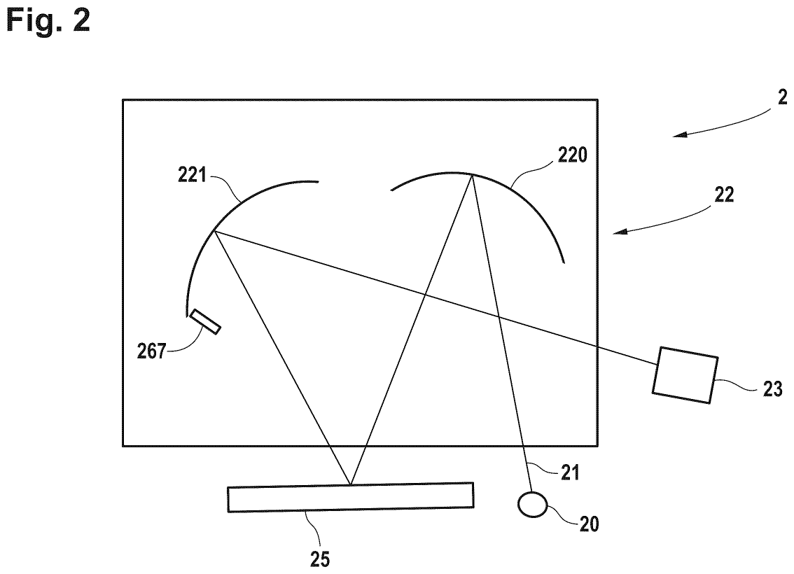

Reflective or transmissive optical elements having a dielectric layer system having at least one nanolayer system can also be used in wafer or mask inspection systems and in optical systems for laser applications. One exemplary embodiment of a wafer inspection system 2 is illustrated schematically in FIG. 2. The explanations are likewise applicable to mask inspection systems.

The wafer inspection system 2 comprises a radiation source 20, the radiation 21 of which is directed onto a wafer 25 by means of an optical system 22. For this purpose, the radiation is reflected from a concave mirror 220 onto the wafer 25. In the case of a mask inspection system, a mask to be examined could be arranged instead of the wafer 25. The radiation reflected, diffracted and/or refracted by the wafer 25 is directed by a concave mirror 221 onto a detector 23 for further evaluation, which is likewise associated with the optical system 22. The radiation source 20 can be, for example, exactly one radiation source or a combination of a plurality of individual radiation sources in order to provide a substantially continuous radiation spectrum. In modifications, one or more narrowband radiation sources can also be used. Preferably, the wavelength or the wavelength band is in the range between 190 nm and 300 nm, particularly preferably between 190 nm and 200 nm. In addition to the two concave mirrors 220, 221, it is also possible to provide lenses in the wafer or mask inspection system.

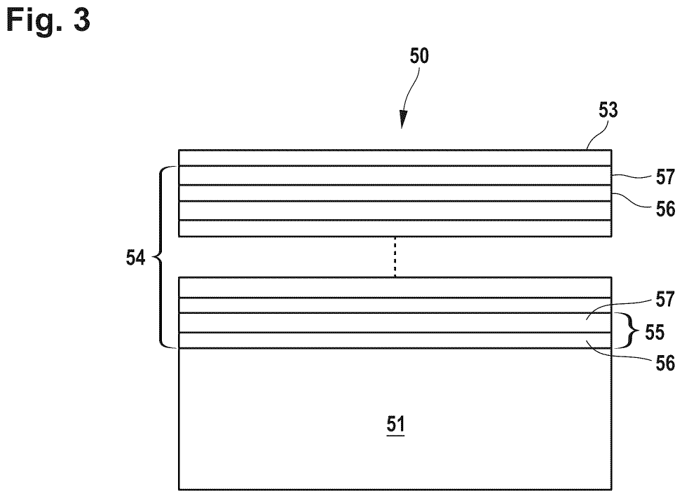

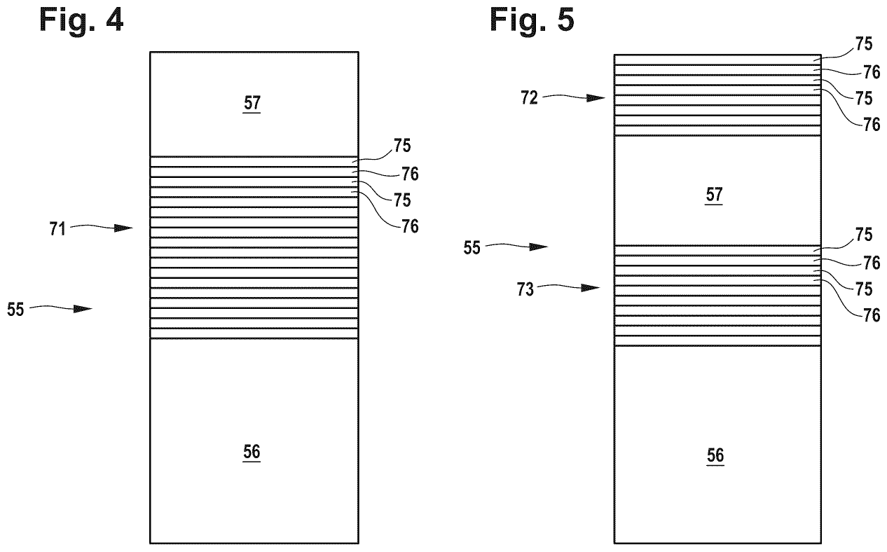

The optical elements for the UV wavelength range as proposed here comprise, on a substrate, an optical coating configured as a dielectric layer system, wherein the dielectric layer system comprises layers of at least two different base materials with different refractive indices at a wavelength in the UV wavelength range, which are arranged alternately, and wherein the optical element comprises a nanolayer system at the position of at least one layer of the base material with the higher refractive index. For the sake of clarity, a nanolayer system is not illustrated in FIG. 3, but more specific details thereof are given in FIGS. 4 and 5.

FIG. 3 schematically illustrates the construction of an optical element 50 for the UV wavelength range, the optical coating of which is based on a dielectric layer system 54. In the example shown here, the dielectric layer system 54 constitutes layers—applied alternately to a substrate 51—of a base material with a lower refractive index at the operating wavelength at which the lithographic exposure, for example, is carried out (also called lower refractive index layer 57) and of a base material with a higher refractive index at the operating wavelength (also called higher refractive index layer 56), wherein a pair composed of lower refractive index and higher refractive index layers 57, 56 forms a layer pair 55. In this case, the optical layer thickness of the layer pair 55 is usually chosen to be near half of the incident wavelength, in order to increase the reflection or transmission. In the example illustrated here, a protective layer 53 can be provided on the side of the dielectric layer system 54 facing away from the substrate, which serves to protect the dielectric layer system 54 from external influences and can optionally be constructed from more than one layer. In variants that are not illustrated, for the case of a reflection coating between the substrate 51 and the dielectric layer system 54, it is possible to provide a metal layer, which can be particularly advantageous for an increased reflection over a wide wavelength range. Depending on the material of, firstly, the substrate 51 and, secondly, the layer of the dielectric layer system 54 that is closest to the substrate, or if appropriate the metal reflective coating, it may be advantageous to provide an adhesion promoter layer therebetween.

FIGS. 4 and 5 each illustrate a layer pair 55 in an enlarged manner. As already explained in connection with FIG. 3, a layer pair 55 respectively comprises a higher refractive index layer 56 and a lower refractive index layer 57. In this case, in the examples illustrated here, the lower refractive index layer 56 is the substrate-facing layer of the layer pair 55. In further variants, the higher refractive index layer 57 can be the substrate-facing layer of the layer pair 55. In the case of transmissive optical elements, the substrate can be a lens body composed of a material which is transparent to the radiation used, i.e., radiation in the UV wavelength range, particularly preferably in the wavelength range of 190 nm to 300 nm, very particularly preferably in the wavelength range of 190 nm to 200 nm. In the case of reflective optical elements, dimensional stability and processability are more influential factors for material selection.

In both examples illustrated in FIGS. 4 and 5, the higher refractive index layer 57 is partly replaced by one nanolayer system 71 in FIG. 4 and by two nanolayer systems 72, 73 in FIG. 5, in order in particular to influence, in particular to reduce, the absorption of the higher refractive index layer 57 in order that the transmission or reflection is increased and less energy is deposited in the dielectric layer system. The individual layers 75, 76 of the nanolayer systems 71, 72, 73 have thicknesses in the nm range, while the layers 56, 57 of the dielectric layer system have thicknesses in the range of a few tens of nanometers. In the example illustrated in FIG. 4, the higher refractive index layer 57 is replaced by the nanolayer system 71 at its side facing the substrate. In the example illustrated in FIG. 5, the higher refractive index layer 57 is replaced both by the nanolayer system 73 at its side facing the substrate and by the nanolayer system 72 at its side facing away from the substrate. In embodiments that are preferred owing to the dictates of production, in particular, both nanolayer systems 72, 73 are constructed from the same materials. If different materials are chosen for both nanolayer systems 72, 73, more possibilities are available for influencing the resulting absorption and also refractive index of the higher refractive index layer 57. In both examples illustrated in FIGS. 4 and 5, the higher refractive index layer 57 is replaced by one or two nanolayer systems 71, 72, 73 over more than half of its thickness. In variants, it is also possible for less than half of the higher refractive index layer to be replaced by a nanolayer system or the higher refractive index layer can be entirely replaced by one or more nanolayer systems.

Particularly if more than one, the majority or even all of the higher refractive index layers of a dielectric layer system comprise(s) one or more nanolayer systems, different higher refractive index layers can be replaced by nanolayer systems to different extents.

In the examples considered here, the nanolayer systems 71, 72, 73 are each constructed from two different nanolayer materials with different refractive indices at a wavelength in the UV wavelength range, the respective layers 75, 76 of which are arranged alternately. It is highly advantageous to choose the higher and/or lower refractive index nanolayer material to be the same material as the respective higher and/or lower refractive index base material of the dielectric layer system. As a result, substantial increases in the transmission or reflection can already be achieved and the outlay/complexity when applying the optical coating can nevertheless be minimized.

Especially for optical elements for wavelengths in the range of 100 nm to 200 nm, preferably 190 nm to 200 nm, what are suitable as a base material with a higher refractive index are oxides, preferably one or more materials of the group consisting of Al₂O₃, MgAl₂O₄, Lu₃Al₅O₁₂, GeO₂, CaO, MgO, HfO₂, Si₃N₄, Y₂O₃, La₂O₃, primarily in combination with silicon dioxide and/or an amorphous fluoropolymer, for instance the commercially available Teflon™ AF, as a base material with a lower refractive index. For wavelengths in the range of 200 nm to 300 nm, inter alia ZrO₂ and Ta₅O₅ are also suitable as higher refractive index material. They can be combined not only with silicon dioxide and/or an amorphous fluoropolymer as lower refractive index material, but also with the higher refractive index materials mentioned for up to 200 nm. The materials mentioned are likewise suitable as higher or lower refractive index nanolayer material, especially if the higher and/or lower refractive index nanolayer material is the same as the respective higher and/or lower refractive index base material.

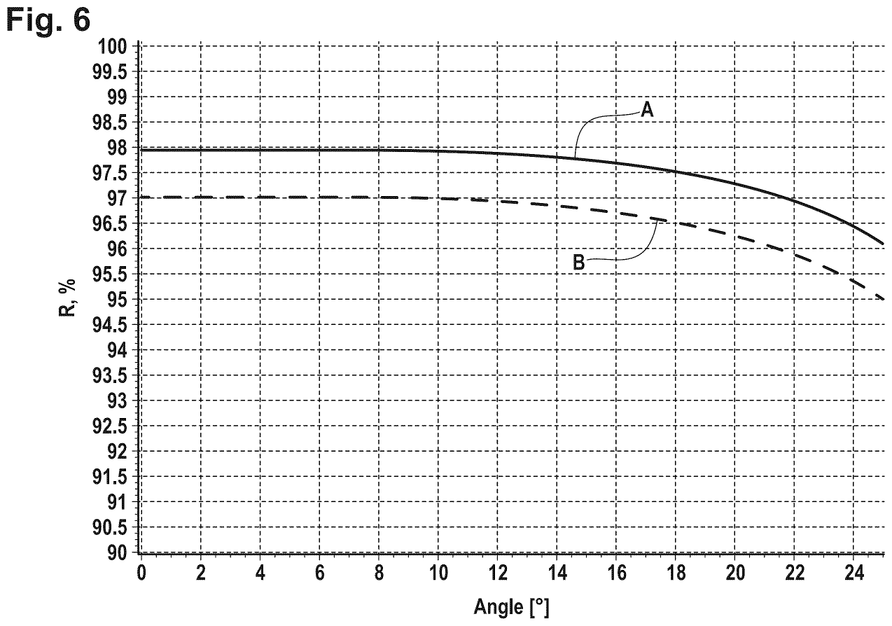

FIG. 6 illustrates the angle dependence of the reflection at a reflective optical element at an incident wavelength of 193 nm. The dashed curve B is the reflection of a conventional reflective optical element which comprises a dielectric layer system composed of SiO₂ as lower refractive index material and Al₂O₃ as higher refractive index material, which is designed for quasi-normal incidence for the wavelength of 193 nm and has a substantially constant reflection of 97% up to an angle of incidence of 10° with respect to the surface normal. The solid curve A, by contrast, is the reflection of a reflective optical element whose dielectric layer system likewise comprises SiO₂ as lower refractive index material and Al₂O₃ as higher refractive index material and is likewise designed for quasi-normal incidence for the wavelength of 193 nm, but in which a plurality of Al₂O₃ layers are partly replaced in each case by a nanolayer system. The nanolayer systems are likewise all constructed from alternately arranged layers of SiO₂ and Al₂O₃. As a result of this measure, the reflection of the optical element is increased to just under 98%, i.e., by more than 1% compared with the conventional optical element.

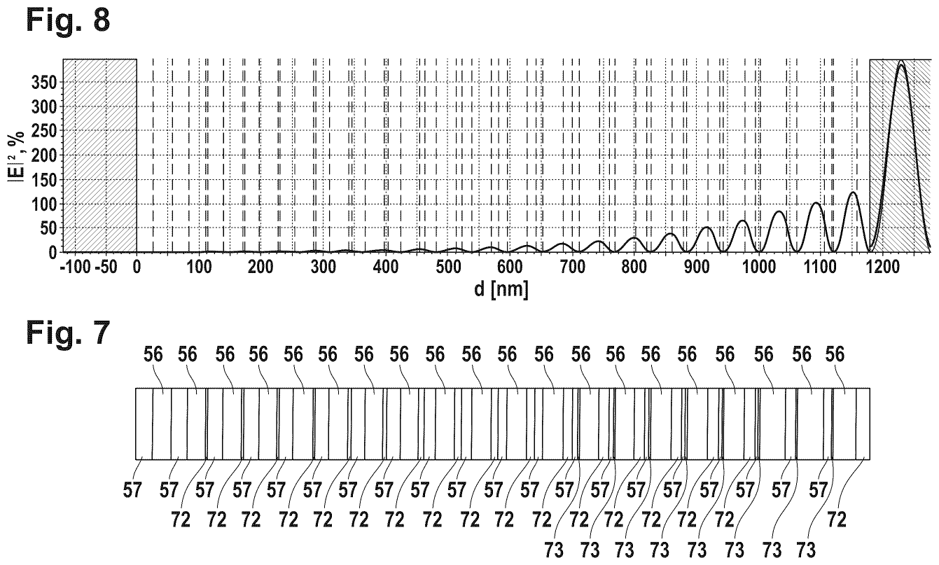

The construction of this dielectric layer system having nanolayer systems is illustrated in FIG. 7. Beginning on the left at the substrate, the optical coating starts with a higher refractive index layer 57 of Al₂O₃, which is followed by a lower refractive index layer 56 of SiO₂. As a rough framework, a total of 20 layer pairs succeed one another, in which higher refractive index layers are partly replaced by nanolayer systems 72, 73 in particular in the third facing away from the substrate, specifically over more than half of their respective thickness in particular in the third facing away from the substrate. The great majority of the higher refractive index layers 57 comprise a nanolayer system 72 composed of Al₂O₃ and SiO₂ at their side facing the substrate. In particular in the third of the coating that faces away from the substrate, the higher refractive index layers 57 also comprise a nanolayer system 73 likewise composed of Al₂O₃ and SiO₂ at their side facing away from the substrate. Toward the surroundings, the optical coating terminates with a layer 72 that completely replaces a higher refractive index layer.

FIG. 8 plots the standing wave as the square of the absolute value of the electric field versus the thickness of the optical coating, said standing wave forming upon reflection at the optical element. The thickness of 0 nm lies at the interface between the dielectric layer system and the substrate. The total thickness of the dielectric layer system amounts to 1175 nm. The layer construction from FIG. 7 is dimensioned and positioned such that the position of the individual layers corresponds to the construction of the optical element from FIG. 8. The nanolayer systems 72, 73 are provided in a targeted manner at points at which the electric field within the respective higher refractive index layer is extremal (maximal in the present plot) and a particularly large amount of radiation energy is therefore absorbed there. By virtue of this measure, in a particularly effective manner, the absorption at the resulting optical element is reduced and hence not only is the reflection or, if appropriate, transmission increased, but also the energy input into the dielectric layer system is decreased and hence the probability of the occurrence of radiation damage is reduced.

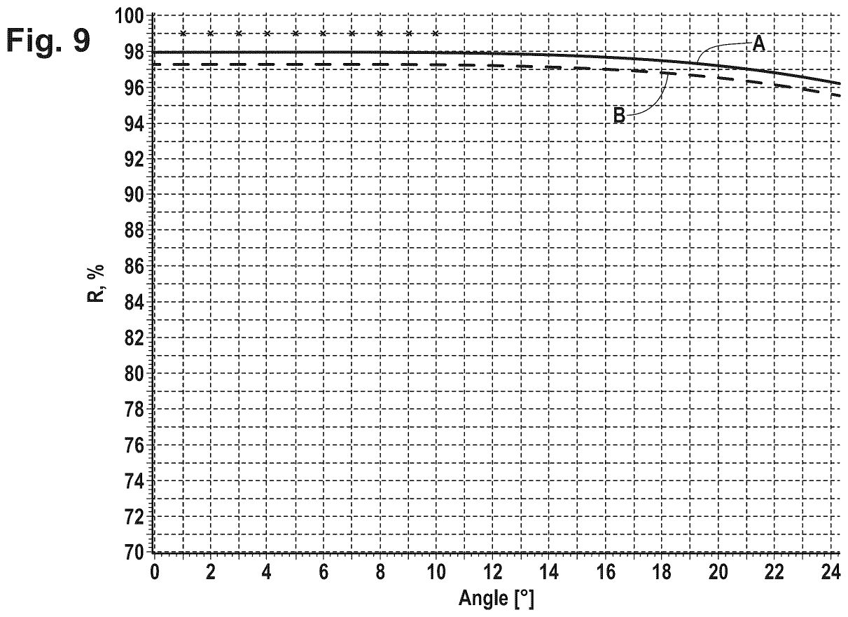

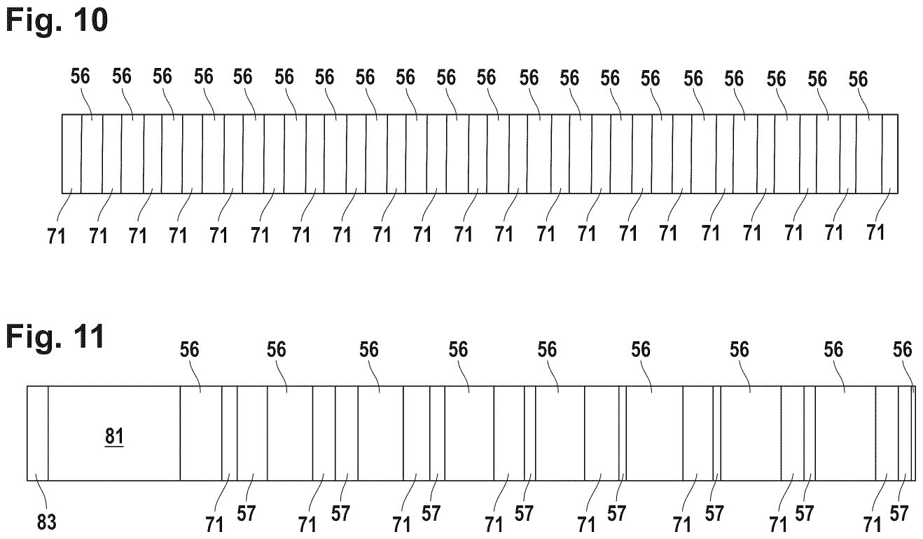

FIG. 9 illustrates the angle dependence of the reflection at a further reflective optical element at an incident wavelength of 193 nm. The dashed curve B is once again the reflection of a conventional reflective optical element which comprises a dielectric layer system composed of SiO₂ as lower refractive index material and Al₂O₃ as higher refractive index material, which is designed for quasi-normal incidence for the wavelength of 193 nm and has a substantially constant reflection of 97% up to an angle of incidence of 10° with respect to the surface normal. The solid curve A, by contrast, is the reflection of a reflective optical element whose dielectric layer system likewise comprises SiO₂ as a lower refractive index material and Al₂O₃ as a higher refractive index material. The reflective optical element of curve A is likewise designed for quasi-normal incidence for the wavelength of 193 nm, but in which all the Al₂O₃ layers of the dielectric layer system of the corresponding conventional optical element are completely replaced in each case by a nanolayer system. The nanolayer systems are all constructed from alternately arranged layers of SiO₂ and Al₂O₃. As a result of this measure, too, the reflection of the optical element is increased to just under 98%, i.e., by more than 1% compared with the conventional optical element. The corresponding layer construction is illustrated in FIG. 10. There is a sequence of 20 layer pairs comprising nanolayer system 71, constructed from alternately arranged SiO₂ and Al₂O₃ layers, and lower refractive index layers 56 of SiO₂. A further layer comprising nanolayer system comprising SiO₂ and Al₂O₃ is arranged toward the surroundings.

FIG. 11 illustrates the construction of the coating of a further embodiment of an optical element proposed here. The latter is embodied as a reflective optical element and additionally comprises a metal layer 81 as part of the reflection coating. An adhesion promoter layer 83 is provided between substrate and metal layer 81 for the sake of better adhesion. In the dielectric layer system, lower refractive index layers 56 and higher refractive index layers 57 are arranged alternately, all the higher refractive index layers 57 being partly replaced by a nanolayer system 71 on the substrate side.

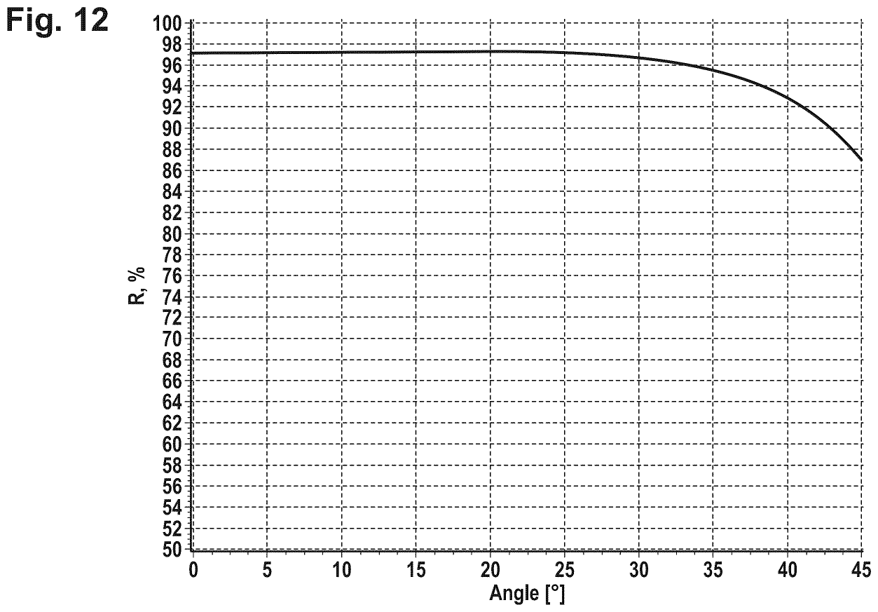

FIG. 12 plots the reflectivity of the coating illustrated in FIG. 11 in the case of an incident radiation of 193 nm versus the angle of incidence. A reflectivity of more than 97% is attained in an angle of incidence range of 0° to 30°. Moreover, the oxidic layers of the dielectric layer system protect the metal layer from ambient influences.

The reflection or transmission increase multiplies in optical systems comprising more than one optical element, with the result that the radiation throughput through the respective optical system can be appreciably increased by the procedure proposed here.

The probability of radiation damage as a result of less energy input into the dielectric layer system of an optical system is decreased for each individual optical element.

It should be pointed out that the exemplary embodiments discussed here in conjunction with FIGS. 6 to 11 are based on SiO₂ as a lower refractive index material and Al₂O₃ a as higher refractive index material. However, the effects described were also able to be achieved with other oxidic layer materials such as, for example, MgAl₂O₄, Lu₃Al₅O₁₂, GeO₂, CaO, MgO, HfO₂, Si₃N₄, Y₂O₃ or La₂O₃ as a higher refractive index material or two or more materials from the group consisting of Al₂O₃, MgAl₂O₄, Lu₃Al₅O₁₂, GeO₂, CaO, MgO, HfO₂, Si₃N₄, Y₂O₃, La₂O₃ as part of the material of the higher refractive index layers and other layers. The effect was also able to be achieved with, for example, Teflon™ AF as a lower refractive index material or SiO₂ and/or as part of the material of the lower refractive index layers and other layers. In the case, too, of optical elements designed for use in transmission instead of in reflection, it was possible to observe an increase in the transmission, especially if the optical element comprises no nanolayer system at the position of the layer arranged the furthest facing away from the substrate.

Owing to their improved transmission or reflection and lifetime, the optical elements described here are suitable, in particular, for use in optical systems for lithography apparatuses or mask or wafer inspection systems for the UV wavelength range and also in optical systems for use with lasers in the UV wavelength range.

### REFERENCE SIGNS

1 VUV lithography apparatus
2 Wafer inspection system
3 Reflective optical element
4 Reflective optical element
5 Reflective optical element
6 Reflective optical element
10 Radiation source
11 Radiation
12 Illumination system
13 Mask
14 Projection system
15 Element to be exposed
20 Radiation source
21 Radiation
22 Optical system
23 Detector
25 Wafer
50 Optical element
51 Substrate
53 Protective layer
54 Dielectric layer system
55 Layer pair
56 Lower refractive index layer
57 Higher refractive index layer
60 Field intensity
61 Minimal field intensity
62 Maximal field intensity
71 Nanolayer system
72 Nanolayer system
73 Nanolayer system
75 Layer
76 Layer
81 Metal layer
83 Adhesion promoter layer
120 Lens
121 Mirror
140 Lens
141 Lens
220 Mirror
221 Mirror
1210 Reflective surface

What is claimed is:

1. An optical element for an ultraviolet (UV) wavelength range, comprising:
a substrate;
an optical coating comprising a dielectric layer system, the dielectric layer system comprising alternating layers of a first base material having a higher refractive index in the UV wavelength range and a second base material having a lower refractive index in the UV wavelength range; and
a nanolayer system partly replacing at least one layer of the first base material.

2. The optical element of claim 1, wherein the optical element is designed for a wavelength of between 190 nm and 300 nm.

3. The optical element of claim 1, wherein the nanolayer system comprises a first nanolayer material with a higher refractive index at a wavelength in the UV wavelength range and second nanolayer material with a lower refractive index at the wavelength in the UV wavelength, which are arranged alternately.

4. The optical element of claim 3, wherein the first nanolayer material is the same as the first base material.

5. The optical element of claim 3, wherein the second nanolayer material is the same as the second base material.

6. The optical element of claim 1, wherein the first base material is selected from the group consisting of Al₂O₃, MgAl₂O₄, Lu₃Al₅O₁₂, GeO₂, CaO, MgO, HfO₂, Si₃N₄, Y₂O₃, La₂O₃.

7. The optical element of claim 1, wherein the second base material comprises silicon dioxide and/or an amorphous fluoropolymer.

8. The optical element of claim 1, wherein the optical coating is configured to reflect radiation at the UV wavelength range, and wherein the at least one layer partly replaced by the nanolayer system is arranged in a third of the optical coating that faces away from the substrate.

9. The optical element of claim 1, wherein the optical coating is configured as a reflective coating at the UV wavelength range, and wherein the at least one layer of the first base material partly replaced by the nanolayer system is one of seven layers of the first base material arranged furthest from the substrate.

10. The optical element of claim 9, wherein a nanolayer system partly replaces five of the seven layers of the first base material arranged furthest from the substrate.

11. The optical element of claim 1, wherein the optical coating is configured as a reflective coating at the UV wavelength range, and wherein the at least one layer of the first base material is at a side of the optical coating facing the substrate.

12. The optical element of claim 1, wherein the optical coating is configured as an antireflection coating, wherein the at least one layer of the first base material is not a layer of the optical coating that is furthest from the substrate.

13. The optical element of claim 1, wherein the at least one layer of the first base material is partly replaced by the nanolayer system at a side facing the substrate and replaced by a second nanolayer system at a side facing away from the substrate.

14. The optical element of claim 13, wherein the nanolayer system and the second nanolayer system are composed of the same materials.

15. The optical element of claim 1, wherein at least half of the at least one layer of the first base material is replaced by the nanolayer system.

16. The optical element of claim 1, configured such that a standing wave of an electric field forms within the optical coating upon reflection of electromagnetic radiation having a wavelength in the vacuum ultraviolet (VUV) wavelength range, wherein the nanolayer system is arranged within the optical coating at a point of extremal field intensity of the standing wave.

17. An optical system, comprising an optical element as claimed claim 1.
